(19) United States
(12) Patent Application Publication
(10) Pub. No.: US 2025/0167124 A1
(43) Pub. Date: May 22, 2025

(54) SEMICONDUCTOR STRUCTURE AND MANUFACTURING METHOD THEREOF

(71) Applicant: Winbond Electronics Corp., Taichung City (TW)

(72) Inventors: Meng-Wei Kao, Kaohsiung City (TW); Keng-Ping Lin, Taichung City (TW); Tzu-Ming Ou Yang, Taichung City (TW); Shu-Ming Li, Kaohsiung City (TW)

(73) Assignee: Winbond Electronics Corp., Taichung City (TW)

(21) Appl. No.: 18/657,791

(22) Filed: May 8, 2024

(30) Foreign Application Priority Data
Nov. 22, 2023 (TW) 112145209

(51) Int. Cl. H01L 23/535; H10B 12/00

(52) U.S. Cl. CPC H01L 23/535; H10B 12/0335; H10B 12/482; H10B 12/485

(57) ABSTRACT

A semiconductor structure includes a substrate, stack structures, first spacers, a contact, and second spacers. The stack structures are located on the substrate and separated from each other. The stack structures include a bit line stack structure and a conductive line stack structure. The first spacers are located on sidewalls of the stack structures. Each of the first spacers includes an oxide layer. The contact is located on the substrate between two adjacent first spacers. The top surface of the oxide layer is not higher than the top surface of the contact. The second spacers are located on the first spacers.

### CROSS-REFERENCE TO RELATED APPLICATION

This application claims the priority benefit of Taiwan patent application serial no. 112145209, filed on Nov. 22, 2023. The entirety of the above-mentioned patent application is hereby incorporated by reference herein and made a part of this specification.

### BACKGROUND

### Field of the Disclosure

The present disclosure relates to a semiconductor structure and a manufacturing method thereof, and in particular, to a semiconductor structure and a manufacturing method thereof that are able to prevent formation of a short circuit between two adjacent landing pads.

### Description of Related Art

In semiconductor components, landing pads are adopted as electrical connection components. However, in the process of forming landing pads, the material layer used to form the landing pads normally cannot be effectively patterned, resulting in formation of a short circuit between two adjacent landing pads.

### SUMMARY

The present disclosure provides a semiconductor structure and a manufacturing method thereof, which are able to effectively prevent the formation of a short circuit between two adjacent landing pads.

The disclosure provides a semiconductor structure, which includes a substrate, multiple stack structures, multiple first spacers, a contact, and multiple second spacers. The stack structures are located on the substrate and separated from each other. The stack structures include a bit line stack structure and a conductive line stack structure. The first spacers are located on sidewalls of the stack structures. Each of the first spacers includes an oxide layer. The contact is located on the substrate between two adjacent first spacers. The top surface of the oxide layer is not higher than the top surface of the contact. The second spacers are located on the first spacers.

The present disclosure provides a method for manufacturing a semiconductor structure. The steps include: providing a substrate; forming multiple stack structures on the substrate, wherein the multiple stack structures are separated from each other, wherein the multiple stack structures include a bit line stack structure and a conductive line stack structure; forming multiple first spacers on sidewalls of the multiple stack structures, wherein each of the first spacers includes a first oxide layer and a first nitride layer; forming a contact on the substrate between the two adjacent first spacers, wherein the first nitride layer is located between the first oxide layer and the contact; the top surface of the first oxide layer and the top surface of the first nitride layer are higher than the top surface of the contact; performing an oxidation process to oxidize a portion of the first nitride layer into a second oxide layer; removing the second oxide layer and a portion of the first oxide layer; forming multiple second spacers on the multiple first spacers.

Based on the above, in the semiconductor structure and the manufacturing method thereof provided by the present disclosure, since the top surface of the oxide layer in the first spacer is not higher than the top surface of the contact, the surface formed by the first spacer and the second spacer may be relatively flat. In this way, in the subsequent process of forming the landing pad, the material layer used to form the landing pad may be effectively patterned to form landing pads that are separated from each other, thereby effectively preventing the formation of a short circuit between two adjacent landing pads.

In order to make the above-mentioned features and advantages of the present disclosure more obvious and easy to understand, embodiments are given below and described in detail with reference to the attached drawings.

### BRIEF DESCRIPTION OF THE DRAWINGS

FIG. 1A to FIG. 1G are cross-sectional views of a manufacturing process of a semiconductor structure according to some embodiments of the present disclosure.

### DETAILED DESCRIPTION OF DISCLOSED EMBODIMENTS

The following embodiments are enumerated and described in detail with reference to the accompanying drawings, but the provided embodiments are not intended to limit the scope of the present disclosure.

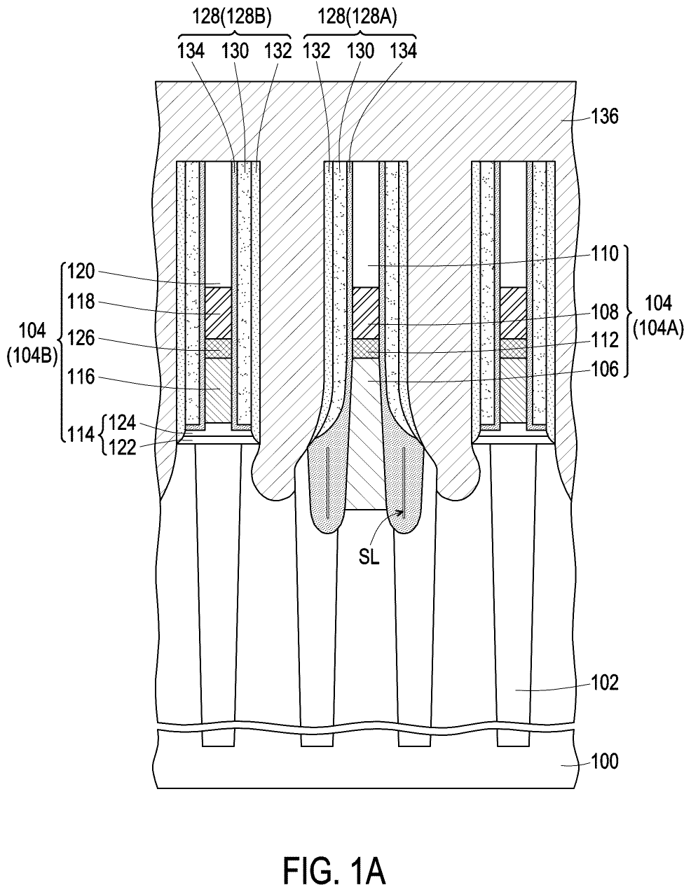

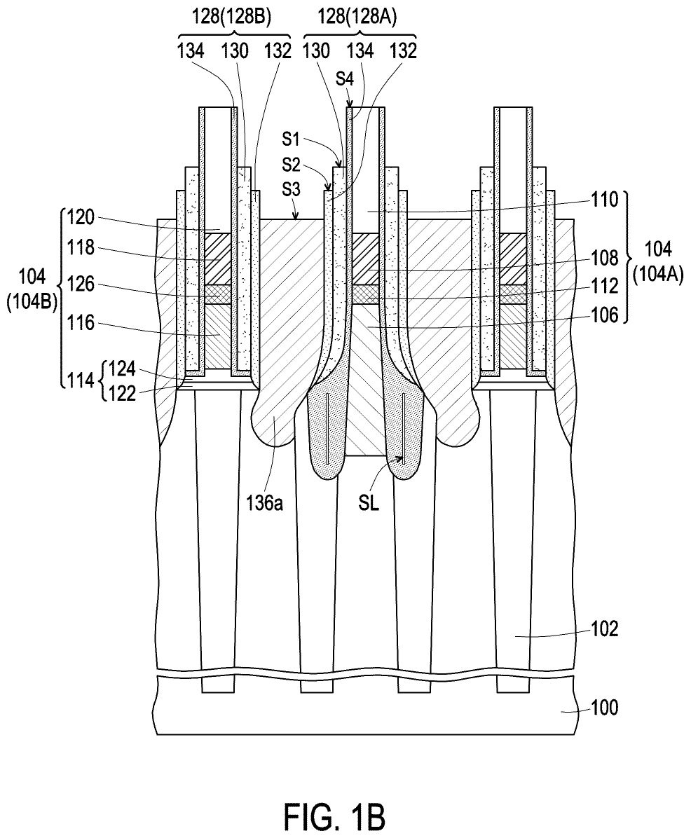

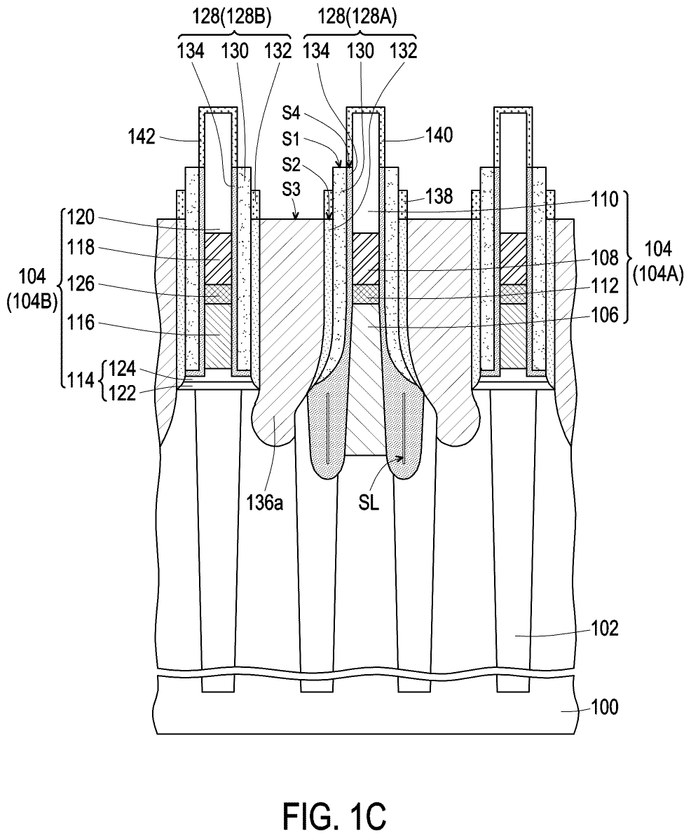

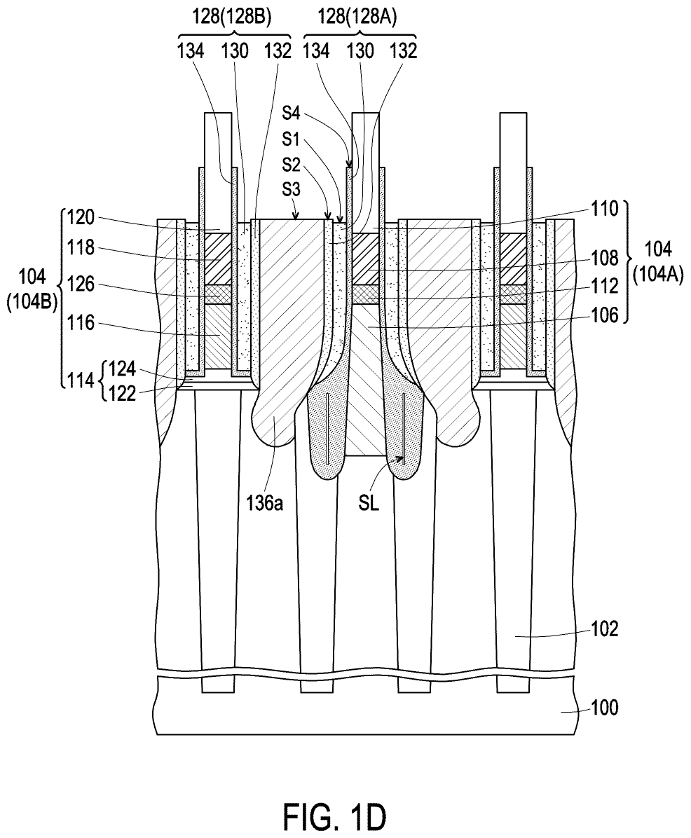

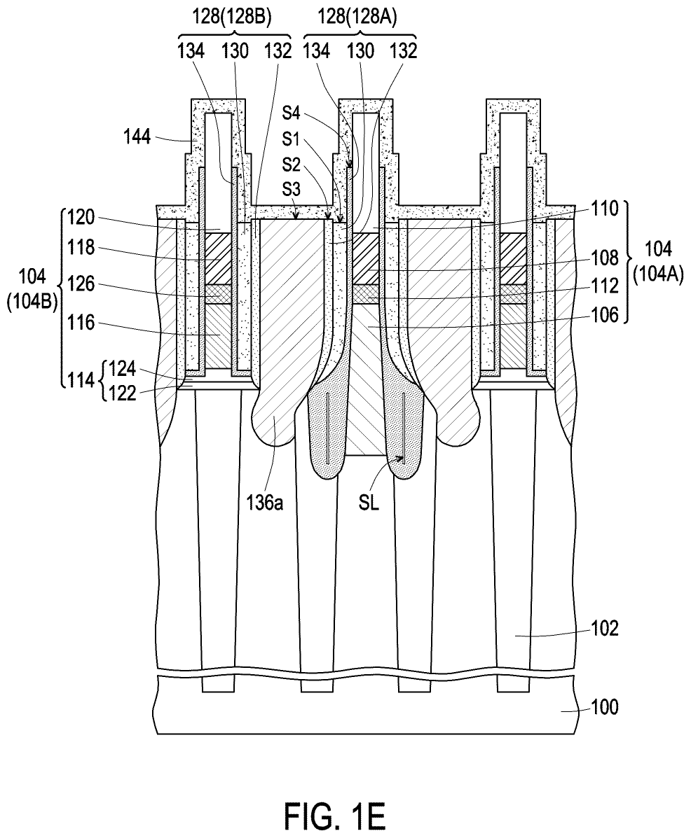

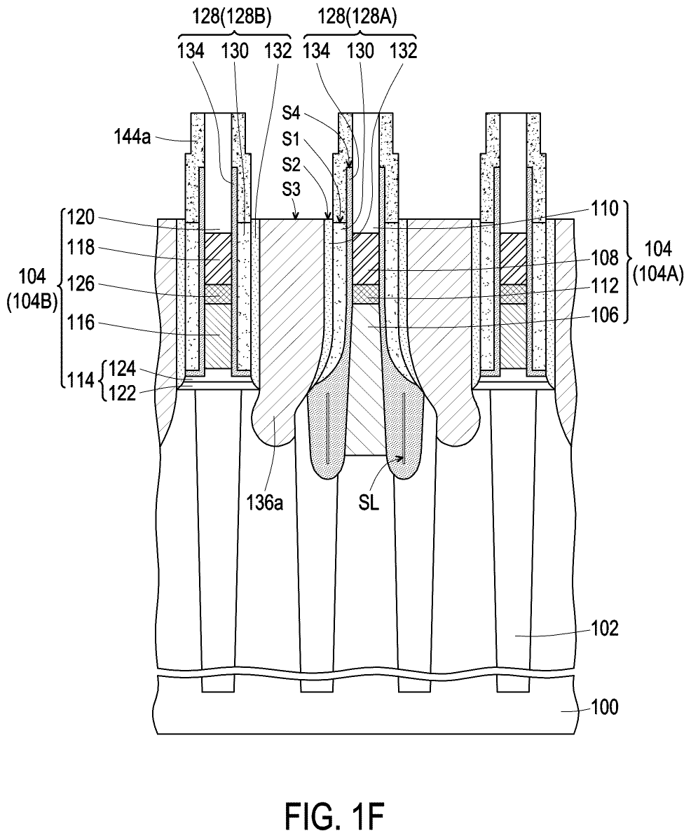

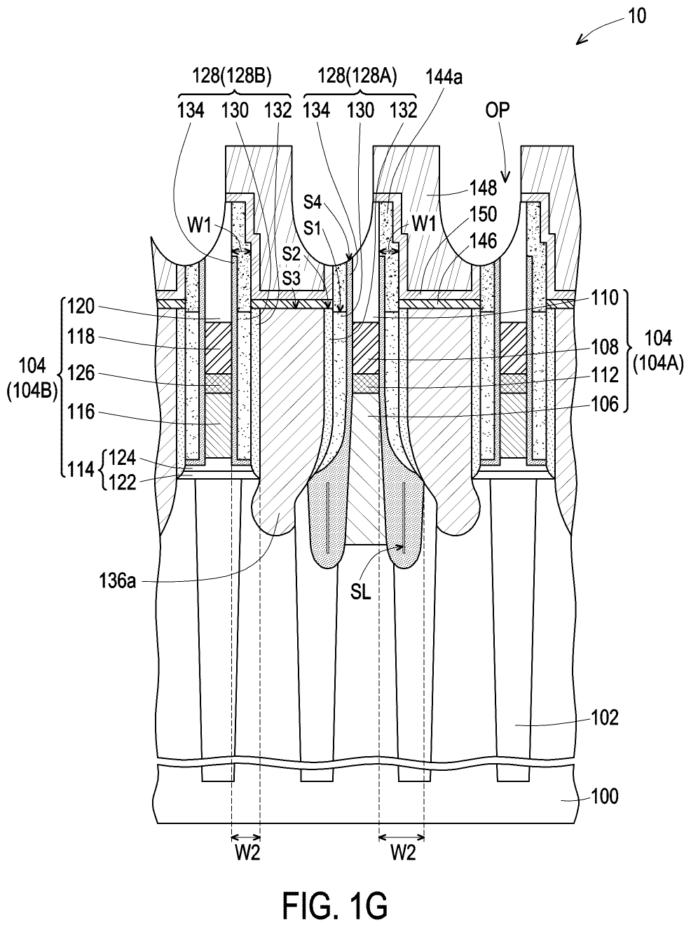

Referring to FIG. 1A, a substrate 100 is provided. The substrate 100 may be a semiconductor substrate, such as a silicon substrate. Additionally, an isolation structure 102 may be formed in the substrate 100. The isolation structure 102 may be a shallow trench isolation structure. The material of the isolation structure 102 may include an oxide (e.g., silicon oxide). In addition, although not shown in the figure, other required components (such as doped regions and/or buried word line structures, etc.) may be formed in the substrate 100.

Next, multiple stack structures 104 are formed on the substrate 100. Multiple stack structures 104 are separated from each other. The multiple stack structures 104 may include a bit line stack structure 104A and a conductive line stack structure 104B. The bit line stack structure 104A may include a bit line contact 106, a bit line 108, and a hard mask layer 110. The bit line contact 106 is located on the substrate 100. The material of the bit line contact 106 may include conductive materials such as doped polysilicon. The bit line 108 is located on the bit line contact 106. The material of the bit line 108 may include conductive materials such as tungsten. The hard mask layer 110 is located on the bit line 108. The hard mask layer 110 may be a single-layer structure or a multi-layer structure. The material of the hard mask layer 110 may include nitride (e.g., silicon nitride). The bit line stack structure 104A may further include a barrier layer 112. The barrier layer 112 is located between the bit line contact 106 and the bit line 108. The material of the barrier layer 112 may include titanium, titanium nitride, or a combination thereof.

The conductive line stack structure 104B may include a dielectric layer 114, a conductive layer 116, a conductive layer 118 and a hard mask layer 120. The dielectric layer 114 is located on substrate 100. The dielectric layer 114 may be located on the isolation structure 102. The dielectric layer 114 may be a single-layer structure or a multi-layer structure. In this embodiment, the dielectric layer 114 may include a dielectric layer 122 and a dielectric layer 124. The dielectric layer 122 is located on the substrate 100. The material of the dielectric layer 122 includes oxide (e.g., silicon oxide). The dielectric layer 124 is located on the dielectric layer 122. The material of the dielectric layer 124 may include nitride (e.g., silicon nitride). The conductive layer 116 is located on the dielectric layer 114. The material of the conductive layer 116 may include conductive materials such as doped polysilicon. The conductive layer 118 is located on the conductive layer 116. The material of the conductive layer 118 may include conductive materials such as tungsten. In some embodiments, the conductive layer 118 and the bit line 108 may be formed simultaneously through the same process. The hard mask layer 120 is located on the conductive layer 118. The hard mask layer 120 may be a single-layer structure or a multi-layer structure. The material of the hard mask layer 120 may include nitride (e.g., silicon nitride). In some embodiments, the hard mask layer 120 and the hard mask layer 110 may be formed simultaneously through the same process. In some embodiments, the conductive line stack structure 104B may further include a barrier layer 126. The barrier layer 126 is located between the conductive layer 116 and the conductive layer 118. The material of the barrier layer 112 may include titanium, titanium nitride, or a combination thereof. In some embodiments, the barrier layer 126 and the barrier layer 112 may be formed simultaneously through the same process.

Then, multiple spacers 128 are formed on the sidewalls of the multiple stack structures 104. The multiple spacers 128 may include a spacer 128A and a spacer 128B. The spacer 128A is located on the sidewall of the bit line stack structure 104A. The spacer 128B is located on the sidewall of conductive line stack structure 104B.

Each spacer 128 includes an oxide layer 130 and a nitride layer 132. The material of the oxide layer 130 may include silicon oxide. The nitride layer 132 is located on one side of the oxide layer 130. The material of the nitride layer 132 may include silicon nitride. Each spacer 128 may further include a nitride layer 134. The nitride layer 134 is located on the other side of the oxide layer 130. The nitride layer 134 is located between the oxide layer 130 and the corresponding stack structure 104. In some embodiments, there may be a slit SL in the nitride layer 134. The material of the nitride layer 134 may include silicon nitride.

Next, a contact material layer 136 may be formed on the substrate 100, the stack structure 104 and the spacer 128. The contact material layer 136 may fill the space between two adjacent spacers 128 (e.g., spacer 128A and spacer 128B). The material of the contact material layer 136 may include conductive materials such as doped polysilicon. The contact material layer 136 may be formed by using a chemical vapor deposition method.

Referring to FIG. 1B, a portion of the contact material layer 136 may be removed to form a contact 136a. In this way, the contact 136a may be formed on the substrate 100 between two adjacent spacers 128 (e.g., the spacer 128A and the spacer 128B). The nitride layer 132 is located between the oxide layer 130 and the contact 136a. In some embodiments, during the process of removing a portion of the contact material layer 136, a portion of the spacer 128 is removed simultaneously. The top surface S1 of the oxide layer 130 and the top surface S2 of the nitride layer 132 are higher than the top surface S3 of the contact 136a. In addition, the top surface S4 of the nitride layer 134 is higher than the top surface S3 of the contact 136a. The method of removing a portion of the contact material layer 136 may include an etch-back method (e.g., dry etching).

Referring to FIG. 1C, an oxidation process (e.g., oxygen plasma oxidation) is performed to oxidize a portion of the nitride layer 132 into the oxide layer 138. The material of the oxide layer 138 may include silicon oxide. During the oxidation process, a portion of the hard mask layer 110 and a portion of the nitride layer 134 may be oxidized into the oxide layer 140, and a portion of the hard mask layer 120 and a portion of the nitride layer 134 may be oxidized into the oxide layer 142. The material of the oxide layer 140 and the oxide layer 142 may include silicon oxide.

Referring to FIG. 1D, the oxide layer 138 and a portion of the oxide layer 130 are removed so that the top surface S1 of the oxide layer 130 is not higher than the top surface S3 of the contact 136a. In this embodiment, the top surface S1 of the oxide layer 130 may be lower than the top surface S3 of the contact 136a, but the disclosure is not limited thereto. In other embodiments, the top surface S1 of the oxide layer 130 may be at the same height as the top surface S3 of the contact 136a. The removal method of the oxide layer 138 and a portion of the oxide layer 130 may include wet etching.

After removing the oxide layer 138, the top surface S2 of the nitride layer 132 may be no higher than the top surface S3 of the contact 136a. In this embodiment, the top surface S2 of the nitride layer 132 may be at the same height as the top surface S3 of the contact 136a, but the disclosure is not limited thereto. In other embodiments, the top surface S2 of the nitride layer 132 may be lower than the top surface S3 of the contact 136a.

In the process of removing the oxide layer 138 and a portion of the oxide layer 130, the oxide layer 140 and the oxide layer 142 may be removed simultaneously. After the oxide layer 140 and the oxide layer 142 are removed, the top surface S4 of the nitride layer 134 may be higher than the top surface S3 of the contact 136a.

Referring to FIG. 1E, a spacer material layer 144 may be formed on the stack structure 104, the spacer 128 and the contact 136a. The material of the spacer material layer 144 may include nitride (e.g., silicon nitride) and the formation method thereof may include chemical vapor deposition.

Referring to FIG. 1F, a portion of the spacer material layer 144 may be removed to form the spacer 144a. In this way, multiple spacers 144a may be formed on the multiple spacers 128. The method of removing a portion of the spacer material layer 144 may include an etch-back method (e.g., dry etching method).

Referring to FIG. 1G, a metal silicide layer 146 may be formed on the contact 136a. The material of the metal silicide layer 146 may include cobalt silicide (CoSi) or nickel silicide (NiSi). In some embodiments, the metal silicide layer 130 may be formed by a self-aligned metal silicide process.

Next, a landing pad 148 may be formed on the contact 136a. The landing pad 148 may be located on metal silicide layer 146. The landing pad 148 is located on one of two adjacent spacers 128 and one of two adjacent spacers 144a. There may be an opening OP on one side of the landing pad 148. The material of the landing pad 148 may include conductive materials such as tungsten. Additionally, the barrier layer 150 may be formed between the landing pad 148 and the contact 136a, between the landing pad 148 and one of the two adjacent spacers 128, or between the landing pad 148 and the other of the two adjacent spacers 128, between the landing pad 148 and one of the two adjacent spacers 144a, and between the landing pad 148 and the other of the two adjacent spacers 144a. The material of the barrier layer 150 may include titanium, titanium nitride, or a combination thereof.

In some embodiments, the method of forming the landing pad 148, the barrier layer 150 and the opening OP may include the following steps. First, a material layer (not shown) for forming the barrier layer 150 and a material layer (not shown) for forming the landing pad 148 may be formed sequentially. Next, the material layer adopted to form the landing pad 148 and the material layer adopted to form the barrier layer 150 are patterned to form the landing pad 148, the barrier layer 150 and the opening OP. In the above patterning process, the material layer adopted to form the landing pad 148 and the material layer adopted to form the barrier layer 150 may be patterned by using a photolithography process and an etching process (e.g., a dry etching process).

In subsequent processes, other required components (such as capacitors, etc.) may be formed to complete the production of semiconductor devices (such as memory devices), and related description is omitted here.

Hereinafter, the semiconductor structure 10 in the above embodiment will be described with reference to FIG. 1G. In addition, although the method for forming the semiconductor structure 10 is described by taking the above method as an example, the present disclosure is not limited thereto.

Referring to FIG. 1G, the semiconductor structure 10 includes a substrate 100, multiple stack structures 104, multiple spacers 128, a contact 136a and multiple spacers 144a. The multiple stack structures 104 are located on the substrate 100 and are separated from each other. The multiple stack structures 104 may include a bit line stack structure 104A and a conductive line stack structure 104B. The multiple spacers 128 are located on the sidewalls of multiple stack structures 104. Each spacer 128 includes an oxide layer 130. The contact 136a is located on the substrate 100 between two adjacent spacers 128. The top surface S1 of the oxide layer 130 is not higher than the top surface S3 of the contact 136a. The multiple spacers 144a are located on the multiple spacers 128. The width W1 of each spacer 144a may be less than the width W2 of each spacer 128. Each spacer 128 may further include a nitride layer 132. The nitride layer 132 is located between the oxide layer 130 and the contact 136a. The top surface S2 of the nitride layer 132 may not be higher than the top surface S3 of the contact 136a. Each spacer 128 may further include a nitride layer 134. The nitride layer 134 is located between the oxide layer 130 and the corresponding stack structure 104. The nitride layer 134 may be located between the corresponding spacer 144a and the corresponding stack structure 104. A portion of the nitride layer 134 may be located directly beneath the silicon oxide layer 130. The top surface S4 of the nitride layer 134 may be higher than the top surface S3 of the contact 136a.

The semiconductor structure 10 may further include a landing pad 148. The landing pad 148 is located on the contact 136a, may be electrically connected to the contact 136a, and may be located on one of the two adjacent spacers 128 and one of the two adjacent spacers 144a. There may be an opening OP on one side of the landing pad 148. The semiconductor structure 10 may further include a barrier layer 150. The barrier layer 150 is located between the landing pad 148 and the contact 136a, between the landing pad 148 and one of the two adjacent spacers 128, between the landing pad 148 and the other of the two adjacent spacers 128, between the landing pad 148 and one of the two adjacent spacers 144a and between the landing pad 148 and the other of the two adjacent spacers 144a.

In addition, description of the remaining components in the semiconductor structure 10 may be derived from the above embodiment. Moreover, the details of each component in the semiconductor structure 10 (such as materials and formation methods, etc.) have been described in detail in the above embodiments and will not be described again.

Based on the above embodiments, it can be seen that in the semiconductor structure 10 and the manufacturing method thereof, since the top surface S1 of the oxide layer 130 in the spacer 128 is not higher than the top surface S3 of the contact 136a, the surface formed by the spacer 128 and the spacer 144a may be relatively flat. In this way, in the subsequent process of forming the landing pad 148, the material layer adopted to form the landing pad 148 may be effectively patterned to form the landing pads 148 separated from each other, thereby effectively preventing the formation of a short circuit between the two adjacent landing pads 148.

The embodiments disclosed above are not intended to limit the present disclosure. Anyone with ordinary knowledge in the technical field can make some modifications and refinement without departing from the spirit and scope of the present disclosure. Therefore, the protection scope of the present disclosure shall be determined by the appended claims.

What is claimed is:

1. A semiconductor structure, comprising:
a substrate;
a plurality of stack structures located on the substrate and separated from each other, wherein the plurality of stack structures comprise a bit line stack structure and a conductive line stack structure;
a plurality of first spacers located on sidewalls of the plurality of stack structures, wherein each of the plurality of first spacers comprises an oxide layer;
a contact located on the substrate between two of the adjacent first spacers, wherein a top surface of the oxide layer is not higher than a top surface of the contact; and
a plurality of second spacers located on the plurality of first spacers.

2. The semiconductor structure according to claim 1, wherein each of the plurality of first spacers further comprises:
a first nitride layer located between the oxide layer and the contact.

3. The semiconductor structure according to claim 2, wherein a top surface of the first nitride layer is not higher than the top surface of the contact.

4. The semiconductor structure according to claim 2, wherein each of the plurality of first spacers further comprises:
a second nitride layer located between the oxide layer and the corresponding stack structure.

5. The semiconductor structure according to claim 4, wherein a top surface of the second nitride layer is higher than the top surface of the contact.

6. The semiconductor structure according to claim 4, wherein a portion of the second nitride layer is located directly under a silicon oxide layer.

7. The semiconductor structure according to claim 4, wherein a portion of the second nitride layer is located between the corresponding second spacer and the corresponding stack structure.

8. The semiconductor structure according to claim 1, wherein a width of each of the plurality of second spacers is smaller than a width of each of the plurality of first spacers.

9. The semiconductor structure according to claim 1, further comprising:
a landing pad located on the contact, wherein the landing pad is located on one of the two adjacent first spacers and one of the two adjacent second spacers, and has an opening on one side of the landing pad.

10. The semiconductor structure according to claim 9, further comprising:
a barrier layer located between the landing pad and the contact, between the landing pad and one of the two adjacent first spacers, between the landing pad and the other of the two adjacent first spacers, between the landing pad and one of the two adjacent second spacers, and between the landing pad and the other of the two adjacent second spacers.

11. The semiconductor structure according to claim 1, wherein the bit line stack structure comprises:
a bit line contact located on the substrate; and
a bit line located on the bit line contact.

12. The semiconductor structure according to claim 1, wherein the conductive line stack structure comprises:
a dielectric layer located on the substrate;
a first conductive layer located on the dielectric layer; and
a second conductive layer located on the first conductive layer.

13. A method for manufacturing a semiconductor structure, comprising:
providing a substrate;
forming a plurality of stack structures on the substrate, wherein the plurality of stack structures are separated from each other, and the plurality of stack structures comprise a bit line stack structure and a conductive line stack structure;
forming a plurality of first spacers on sidewalls of the plurality of stack structures, wherein each of the plurality of first spacers comprises a first oxide layer and a first nitride layer;
forming a contact on the substrate between the two adjacent first spacers, wherein the first nitride layer is located between the first oxide layer and the contact, a top surface of the first oxide layer and a top surface of the first nitride layer are higher than a top surface of the contact;
performing an oxidation process to oxidize a portion of the first nitride layer into a second oxide layer;
removing the second oxide layer and the portion of the first oxide layer; and
forming a plurality of second spacers on the plurality of first spacers.

14. The method for manufacturing the semiconductor structure according to claim 13, after removing the second oxide layer and the portion of the first oxide layer, the top surface of the first oxide layer is not higher than the top surface of the contact.

15. The method for manufacturing the semiconductor structure according to claim 14, wherein the top surface of the first nitride layer is not higher than the top surface of the contact.

16. The method for manufacturing the semiconductor structure according to claim 13, wherein the method for removing the second oxide layer and the portion of the first oxide layer comprises a wet etching method.

17. The method for manufacturing the semiconductor structure according to claim 13, wherein
the bit line stack structure comprises:
a bit line contact located on the substrate;
a bit line located on the bit line contact; and
a first hard mask layer located on the bit line,
the conductive line stack structure comprises:
a dielectric layer located on the substrate;
a first conductive layer located on the dielectric layer;
a second conductive layer located on the first conductive layer; and
a second hard mask layer located on the second conductive layer, and
each of the plurality of first spacers further comprises:
a second nitride layer located between the first oxide layer and the corresponding stack structure.

18. The method for manufacturing the semiconductor structure according to claim 17, wherein
in the oxidation process, a portion of the first hard mask layer and a portion of the second nitride layer are oxidized into a third oxide layer, and a portion of the second hard mask layer and a portion of the second nitride layer are oxidized to a fourth oxide layer, and
in the process of removing the second oxide layer and the portion of the first oxide layer, the third oxide layer and the fourth oxide layer are removed simultaneously.

19. The method for manufacturing the semiconductor structure according to claim 13, further comprising:
forming a landing pad on the contact, wherein the landing pad is located on one of the two adjacent first spacers and one of the two adjacent second spacers, and has an opening on one side of the landing pad.
